(19) United States
(12) Patent Application Publication
(10) Pub. No.: US 2025/0324516 A1
(43) Pub. Date: Oct. 16, 2025

(54) METHOD FOR CLEANING A NONCONDUCTIVE SURFACE AND USE

(71) Applicant: ATOTECH DEUTSCHLAND GMBH & Co. KG, Berlin (DE)

(72) Inventor: Jimmy LIN, Berlin (DE)

(73) Assignee: ATOTECH DEUTSCHLAND GMBH & Co. KG, Berlin (DE)

(21) Appl. No.: 18/870,197

(22) PCT Filed: Jun. 13, 2023
(86) PCT No.: PCT/EP2023/065723

§ 371 Date: Nov. 27, 2024

(30) Foreign Application Priority Data
Jun. 14, 2022 (EP) 22178907.6

(51) Int. Cl. H05K 3/00; H05K 3/10

(52) U.S. Cl. CPC H05K 3/0055; H05K 3/108; H05K 2203/0789; H05K 2203/0793; H05K 2203/0796

(57) ABSTRACT

The invention relates to a method for cleaning a nonconductive surface of a nonconductive layer, wherein the nonconductive layer is basing on a composite of an organic polymer and the glass filler and comprising a blind micro via (BMV), for manufacturing an article with an integrated circuit, wherein the nonconductive surface comprises a nonconductive wall surface of the BMV, wherein the nonconductive layer is attached to a copper layer and wherein the copper layer forms the bottom of the BMV, wherein the method comprises the steps in the following order: (i) providing the non-conductive surface of the nonconductive layer; (ii) treating the provided surface with a desmear process comprising the following steps in this order: (t1) treatment with a sweller solution comprising water and an organic solvent, (t2) treatment with an aqueous etching solution comprising an oxidation agent, and (t3) treatment with an aqueous reduction solution comprising a reduction agent; (iii) treating the surface treated in step (ii) with an aqueous alkaline cleaner solution in order to remove the glass filler, wherein the aqueous alkaline cleaner solution; and (iv) drying the surface treated in step (iii) in order to get a dry surface, preferably water-free surface; and a use of the method.

### FIELD OF THE INVENTION

The present invention relates to a novel method for cleaning a nonconductive surface of a nonconductive layer, basing on a composite of an organic polymer and the glass filler and comprising a blind micro via (BMV), for manufacturing an article with an integrated circuit, and the use thereof. In particular the method is used to remove glass filler from the nonconductive surface including the wall surfaces of the blind micro vias and in particular for providing a cleaned surface for subsequent pretreating and metallization in the manufacturing of articles e.g. multilayer assemblies as printed circuit boards, especially fine line IC substrate boards, wherein circuit features as blind micro vias can be filled with metal. The method is in particular useful for SAP applications.

### BACKGROUND OF THE INVENTION

Facing a demand for increasing miniaturization, modern electronics manufacturers must pursue the trend to more and more densely interconnected multilayer printed circuit boards. Owing to their low cost and well-balanced physicochemical and mechanical properties, epoxy-based composites are insulating materials of prime choice. The latest epoxy built-up laminates contain increasing amounts of spherical glass filler, which are needed to compensate the CTE mismatch between the epoxy-based resin matrix and the electroplated copper circuits. In addition, their small size in the order of μm and below, allows for smoother surface topographies compared to glass fiber bundle reinforced base materials.

After inserting different recesses as traces, blind micro vias (BMVs) or through holes (THs) by mechanical or laser drilling into the resin-based substrate comprising the glass filler, a sequence of different wet chemical processes is applied to the surface of a substrate. Such processes are a wet-chemical desmear process to remove residues of the drilling process, followed by a pretreatment process to prepare the surface for subsequent electroless and/or electrolytic metallization. During industrial desmear processing the adhesion of the exposed glass filler at the surface of the substrate and at the surface of the recesses will be weakened and their anchoring in the surrounding resin matrix will be lost or damaged. If these fillers will not be removed, the remaining weak-bounded or loose filler may give rise to low adhesion of plated copper on the epoxy resin, as well as contaminated copper to copper connections in blind micro vias or through holes (TH). This can affect yield rates in production and reliability in the final product.

Common approaches to overcome the glass filler contamination include fluoride etch solutions described in US 2012/0298409 A1 and ultrasonic treatment described in US 2007/0131243 A1. Neither of these strategies is easily applicable in the vertical mode of semi additive processing (SAP). The drastic health issues of fluoride etching solutions quickly disqualify them for most parts of the industry, whereas ultrasound application in vertical mode, possibly even in basket application, is extremely difficult to employ in a homogeneous fashion with sufficiently high impact on each panel.

JP 2010-229536 A discloses a pretreatment agent for cleaning surface of a resin substrate containing silica-based filler wherein the filler and the glass fiber shall be removed which are exposed on the substrate surface after desmear treatment etc. The pretreatment agent includes an alkali, a nonionic ether type surfactant, and an amine-based complexing agent.

US 2010/056416 A1 discloses a cleaning composition with a limited number of natural ingredients containing an anionic surfactant, a hydrophilic syndetic selected from a C6 alkylpolyglucoside, nonionic surfactant and a hydrophobic syndetic such as oleic or palmitic acid, wherein the composition has a pH 7 to 13. The cleaning composition can be used to clean laundry, soft surfaces, and hard surfaces.

In particular in SAP applications, which needs metallization of the whole surface of the nonconductive substrate to start the SAP application, cleaning and plating of the substrate cannot be achieved with good reliability.

Beside the mentioned problems of providing good cleaning and plating compositions for constantly new offered substrate materials and treatment chemistry, also the processes for cleaning and plating have to be adapted permanently. For example, a desmear process takes more and more time and more precaution due to new materials compared to the subsequent process steps in pretreating and metallization. In particular, a good crossover from one part of a process sequence to another part or from one treatment bath to another bath bear problems due to evolving material characteristics after treatment, drag out problems, different holding and processing times, etc. within the whole metallization process of the nonconductive material.

### OBJECTS OF THE INVENTION

Therefore, it is an object of the present invention to overcome shortcomings of the prior art and to provide means for improved cleaning including the removing of loose glass filler from the nonconductive surface of a wide variety of composites having organic polymers and glass filler wherein the glass filler is exposed on the composite surface after drilling recess structures as blind micro vias or through holes and having low adhesiveness.

It is a further an object of the present invention to provide means for preparing a cleaned nonconductive surface after drilling of recess structures as blind micro vias, which allows improved peel strength results after metallization.

It is still another object of the present invention to provide means for improved removing of glass filler which improves the handling of the different process steps and flexibility in using new treatment bath compositions.

It is still another object of the present invention to improve the adsorption and achieving a uniform distributed deposition of an activator as a palladium catalyst onto the surface of the substrate imparting the catalyst to enhance adhesiveness of the subsequent copper plating and improve copper adhesion reliability. At the same time the consumption of activator shall be as low as possible.

It is still another object of the present invention to use the means for the manufacturing of electronic articles as multilayer assembly as fine line IC substrates, preferably basing on SAP applications.

### SUMMARY OF THE INVENTION

These objects are solved with the present invention.

In one aspect of the present invention, it is provided:
a method for cleaning a nonconductive surface of a nonconductive layer, wherein the nonconductive layer is basing on a composite of an organic polymer and the glass filler and comprising a blind micro via (BMV), for manufacturing an article with an integrated circuit, wherein the nonconductive surface comprises a nonconductive wall surface of the BMV, wherein the nonconductive layer is attached to a copper layer and wherein the copper layer forms the bottom of the BMV, wherein the method comprises the steps in the following order:
(i) providing the nonconductive surface of the nonconductive layer;
(ii) treating the provided surface with a desmear process comprising the following steps in this order: treatment with a sweller solution comprising water and an organic solvent, treatment with an aqueous etching solution comprising an oxidation agent, and treatment with an aqueous reduction solution comprising a reduction agent, in order to obtain a desmear treated surface;
(iii) treating the surface treated in step (ii) with an aqueous alkaline cleaner solution in order to remove the glass filler, wherein the aqueous alkaline cleaner solution comprises:
(a) at least one surfactant selected from the group consisting of saturated branched or unbranched C5 to C12 carboxylic acid or salt thereof, wherein the concentration of the
(a) at least one surfactant is from 0.9 to 1.7 g/L;
(b) at least one surfactant selected from the group consisting of saturated branched or unbranched C5 to C12 alkyl having a negatively charged group selected from sulfate, sulfite, sulfonate phosphate, phosphite and carbonate, and saturated C3-C8 alkyl amino carboxylate;
(c) at least one compound having at least one hydroxyl group and at least one C—O—C group wherein the compound is selected from the group consisting of alkoxylated C5-C12 alkanol and glycosidic C5-C12 alkanol; and
(d) alkali metal hydroxide, wherein the concentration of the (d) alkali metal hydroxide is from 65 to 200 g/L;
(iv) drying the surface treated in step (iii) in order to get a dry surface, preferably water-free surface.

In another aspect of the present invention, it is provided a use of the method above for SAP (semi-additive process) applications in manufacturing an article with an integrated circuit having line/space dimensions from 25/25 μm to 8/8 μm or less.

Further aspects of the present invention could be learned from the dependent claims or the following description.

### BRIEF DESCRIPTION OF THE DRAWINGS

Features will become apparent to those of ordinary skill in the art by describing in detail exemplary embodiments with reference to the attached drawings in which:

FIG. 1 illustrates the results of the cleaning performance on the nonconductive surface by SEM.

### DETAILED DESCRIPTION OF THE INVENTION

Reference will now be made in detail to embodiments, examples of which are illustrated in the accompanying drawings. Effects and features of the exemplary embodiments, and implementation methods thereof will be described with reference to the accompanying drawings. In the drawings, like reference numerals denote like elements, and redundant descriptions are omitted. As used herein, the term “and/or” includes any and all combinations of one or more of the associated listed items. Further, the use of “may” when describing embodiments of the present invention refers to “one or more embodiments of the present invention”.

In the following description of embodiments of the present invention, the terms of a singular form may include plural forms unless the context clearly indicates otherwise, e.g. if in the following ‘filler’ or ‘blind micro via’ is used ‘fillers’ or ‘blind micro vias’ is included.

The following description also uses the term ‘substrate’ or ‘nonconductive surface of the substrate’ to simplify reading. In this context the substrate is built of the nonconductive layer attached to the copper layer, wherein the substrate has the nonconductive surface of the nonconductive layer to be treated by the invention and the copper surface of the copper layer, building also the bottom of the blind micro via drilled into the nonconductive layer.

An aqueous solution in the context of the present invention is a solution which contains more than 50 weight-% of water.

In the context of the present invention, the oxidation agent is suitable to oxidize a compound or material in particular the nonconductive surface of the nonconductive layer wherein the oxidation agent is reduced. With other words, the oxidation agent is a substance in a redox chemical reaction that gains or “accepts”/“receives” an electron from a reducing agent e.g. the nonconductive surface or more precise the material of said surface.

In the context of the present invention, the reducing agent is suitable to reduce a compound in particular a compound onto the oxidized nonconductive surface of the nonconductive layer wherein the reducing agent is oxidized. With other words, the reducing agent is a substance in a redox chemical reaction that donates an electron from the reducing agent to the compound to be reduced e.g. a compound onto the nonconductive surface.

The present invention is in particular suited to be used with a desmear treatment combined with glass filler removal treatment and before pretreatment preferably comprising palladium activation of the before treated nonconductive surface according to the invention, wherein the composite comprises glass filler as spherical glass filler, being e.g. part of SAP base materials. With the present invention it is possible to remove the exposed glass filler from the surface including the wall surface of BMVs and also through holes (THs) which became loose or less attached during drilling and desmear process and to provide a treated surface such that the adhesion of subsequent deposited metal layers is improved. The invention provides cleaned surfaces of the nonconductive layer including the nonconductive wall surface of the BMVs and also (THs) for subsequent electroless and/or electrolytic metallization processes starting with pretreating the dry surface.

In one embodiment, where the nonconductive surface also includes the wall surface of THs, the trough holes are going through from the surface of the nonconductive surface to the surface of the copper layer to build said THs.

The present invention in particular allows to separate a pretreating process from a cleaning process including a desmear process within the complete metallization process, which is normally done in a close follow-up of all single process steps in a wet in wet sequence. This leads to more flexibility between these two important processes in view of longer time needed for desmear process and/or in view of alternative used bath compositions for the pretreating.

The invention leads to higher yield rates and better reliability of the manufactured multilayer assemblies as printed circuit boards wherein the adhesion properties on industrially relevant IC substrate and printed circuit board substrates have shown significantly higher peel strength values after treatment with the new process.

In particular the invention enables the manufacturing of electronic article with an integrated circuit e.g. an IC substrate article having line/space dimensions (L/S) from 25/25 μm down to 8/8 μm, preferably from 15/15 μm to 8/8 μm, or more preferably less than 8/8 μm. At the same time, the process provides excellent coverage performance.

The invention uses less hazardous components than used in the prior art. Further the invention enables the manufacturing of electronic article under milder conditions in view of working temperature and working time. This leads to considerable reduced energy consumption and improves throughput. Lower temperature schemes also reduce the equipment and maintenance costs.

One of the most desired benefits of cleaning the nonconductive surfaces from loose glass filler is an increase of adhesion of the plated copper to the cleaned surface. An obvious reason for anticipating this adhesion increase would be to assume an insufficient bonding of ‘loose’ glass filler to the substrate. This should be the case for filler that is less than half embedded in the surrounding epoxy resin after desmear or for any re-adsorbed filler. Copper is then plated around this filler and upon exertion of peeling forces, they are easily lifted from the substrate. Surprisingly, the drying step further improved the adhesion of the subsequent deposited metal layers and also leads to improved distribution of the activator while reducing the amount of activator density. Last effect in particular helps to save money and resources.

The invention can be used in a wide range of different substrates of different suppliers wherein nonconductive layer is basing on a composite of organic polymers and glass filler, wherein the copper layer is attached to the nonconductive layer, e.g. by lamination, which builds the substrate to be treated.

The composite is basing on mixture of glass filler and/or silica filler with organic polymers as resins and/or plastics, and blends thereof. Resins and plastics include dielectric materials typically used in the electronics industry which are to be metallized. Resins and plastics are preferably selected from epoxy as epoxy resin, isocyanate resin, bismaleimide triazine resin, and phenylene resin; polyester such as polyethylene terephthalate (PET), polyimide (PI), polytetrafluorethylene, acrylonitrile-butadiene-styrene (ABS) copolymer, polyamide (PA), polycarbonate (PC) as well as mixtures and blends of the aforementioned.

The organic polymers more preferably comprise polyimide resins or epoxy resins wherein the polyimide resins can be modified by the addition of polysiloxane, polycarbonate, polyester or the like. The epoxy resins can be glass filler epoxy board material comprising a combination of the epoxy resin and glass filler, or the same modified to have a low thermal expansion and a high glass-transition temperature, constituting a high glass-transition temperature glass filler epoxy board material.

Suitable glass filler is preferably selected from borosilicate glass, quartz glass, silica glass, fluorinated glass. The size of different filler has a range from 0.01 μm to 5 μm in diameter with preferably an average of 0.5 μm in diameter.

Preferable the composite of the nonconductive layer is a build-up film, e.g. epoxy base materials. Detailed names will be given where necessary. The size of the embedded glass filler has an average of 0.5 μm in diameter, with a maximum of 5.0 μm.

The substrate according to the invention can comprise a core layer. In this case the copper layer attached to the nonconductive layer is further attached to the core layer. This core layer makes the handling of the more flexible substrate easier and avoids undesired twisting of the substrate.

In a further embodiment, two substrates can be attached to a core layer. In this case, the copper layer of each substrate is attached to the core layer while the nonconductive layer is the outer layer. This enables the nonconductive layer of the two substrates comprising one core layer to be treated and to build up multilayer assemblies from both sides of the core layer.

The aforementioned core layer can be selected from the group consisting of printed circuit board substrates, circuit carrier substrates, interconnect devices substrates and precursors for any of the aforementioned. Such substrates and precursors include inter alia flame retardant NEMA-graded materials as FR-1, FR-2, FR-3, FR-4, FR-5 (FR-1, FR-2, FR-3, FR-4 and FR-5 are PCB dielectric materials with good electrical specifications known to the skilled person e.g. made of paper and phenol-formaldehyde resin (FR-1), woven/unwoven fibre-glass cloth impregnated with epoxy resin (FR-4) or fiber-glass fabric reinforced with high temperature epoxy resin binder (FR-5)), copper-clad materials, SAP material, an IC substrate and laminates thereof, preferably the core layer is a FR4 material, SAP material or an IC substrate.

The desmear process in step (ii) is performed before step (iii), preferably without any further wet-chemical step as a rinsing step.

The desmear process comprises sub-steps (t1), (t2) and (t3),
wherein (t1) comprises treatment with a sweller solution comprising water and an organic solvent of the nonconductive surface of a nonconductive layer to obtain a swollen surface,
wherein (t2) comprises treatment with an aqueous etching solution, comprising an oxidation agent, of the swollen surface to obtain an etched surface, and
wherein (t3) comprises treatment with an aqueous reduction solution comprising a reduction agent of the etched surface to obtain a desmear-treated surface.

By applying the corresponding sub-steps (t1), (t2) and (t3) a particularly effective desmear process can be ensured wherein the main part of the residues (so-called smear) derived from the drilling process is removed.

The sweller solution penetrates the nonconductive surface of a nonconductive layer which leads to a swollen surface wherein the bonding strength of (weakly) bound particle as glass filler or drilling residues within said surface will be further weaken. Preferably, the organic solvent of the sweller solution is selected as glycol ether and/or lactams, and penetrates into the exposed resin surface of through holes and BMVs. Most preferably, the solution is selected as the commercially available Securiganth MV Sweller.

Preferably, the organic solvent is applied to the water-containing sweller solution at a concentration from 300 ml/L to 650 ml/L, preferably 350 ml/L to 550 ml/L, more preferably 450 ml/l to 550 ml/l based on the total volume of the sweller solution.

Preferably, the sweller solution has a pH from 9.5 to 12, preferably 10.5 to 11.5.

Preferably, (t1) is performed at a temperature of 55° C. to 90° C., preferably 70° C. to 85° C., for a duration from 2 min to 10 min, preferably 4 to 5 min.

The aqueous etching solution of (t2) may comprise an oxidation agent, more preferably hydrogen peroxide and sulfuric acid. Preferably, the aqueous etching solution is selected as an alkaline aqueous etching solution, more preferably a potassium or sodium hydroxide solution, and comprises an oxidation agent, more preferably potassium permanganate. Most preferably, the etching agent is selected as the commercially available Securiganth P500 or Securiganth MV P-Etch.

Preferably, (t2) the treatment with an aqueous etching solution, preferably comprising permanganate is applied at a concentration from 50 g/l to 70 g/L, preferably 55 g/l to 65 g/L based on the total volume of the aqueous etching solution.

Preferably, (t2) is performed at a temperature of 70° C. to 90° C. for a duration from 5 min to 25 min, preferably 8 min to 15 min.

The aqueous reduction solution (t3) comprises a reduction agent as hydroxylammonium sulfate or hydrogen peroxide and preferably an acid, most preferably sulfuric acid or hydrochloric acid, wherein the reduction agent is capable to reduce metal leftovers from the previous step. Optionally the aqueous reduction solution (t3) can use a conditioner compound to obtain an aqueous reduction conditioner solution. The aqueous reduction conditioner solution preferably comprises an acid such as sulfuric acid or hydrochloric acid, an agent capable of reducing, e.g. manganese dioxide being onto the surface of the nonconductive surface after applying the aqueous etching solution of (t2), such as hydroxylammonium sulfate or hydrogen peroxide and a polymer containing quaternized nitrogen atoms. E.g. Securiganth® MV Reduction Solution or Securiganth® MV Reduction Conditioner available from Atotech Deutschland GmbH can be used.

Preferably, (t3) is performed at a temperature from 40° C. to 55° C. for a duration from 3 min to 7 min.

Step (iii) treating the surface treated in step (ii) with an aqueous alkaline cleaner solution:

By applying the step (iii) after the desmear process, remaining parts of the residues derived from the drilling process are removed, but more important now loose glass filler will be sufficiently removed.

The concentration of the at least one surfactant (a) in aqueous alkaline cleaner solution is used from 0.9 to 1.7 g/L, preferably from 1.0 to 1.5 g/L, more preferably from 1.2 to 1.4 g/L. In case of two or more surfactants in the solution, the total concentration is also from 0.9 to 1.7 g/L, preferably from 1.0 to 1.5 g/L, more preferably from 1.2 to 1.4 g/L. It is understood that the surfactant can be added as acid or salt.

The concentration of the at least one surfactant (b) in aqueous alkaline cleaner solution is preferably used from 0.5 to 10 g/L, more preferably from 1.5 to 9 g/L, most preferably from 2 to 8 g/L. Other preferred concentration ranges are from 0.5 to 1.2 g/L, preferably from 0.7 to 1.1 mg/L more preferably from 0.75 to 1.0 g/L. In case of two or more surfactants in the solution, the total concentration is also from 0.5 to 10 g/L. In one preferred embodiment the concentration range of the at least one surfactant (b) selected from the group consisting of saturated branched or unbranched C5 to C12 alkyl having a negatively charged group selected from sulfate, sulfite, sulfonate phosphate, phosphite and carbonate is from 0.5 to 1.2 g/L, preferably from 0.7 to 1.1 mg/L more preferably from 0.75 to 1.0 g/L. In another preferred embodiment the concentration range of the at least one surfactant (b) selected from the group consisting of saturated C3-C8 alkyl amino carboxylate 0.5 to 10 g/L, preferably from 1.5 to 9 g/L, more preferably from 2 to 8 g/L.

The concentration of the at least one compound (c) having at least one hydroxyl group and at least one C—O—C group in aqueous alkaline cleaner solution is preferably used from 0.7 to 1.3 g/L, more preferably from 0.8 to 1.2 g/L, most preferably from 0.9 to 1.1 g/L. In case of two or more alkanols in the solution, the total concentration is also from 0.7 to 1.3 g/L, preferably from 0.8 to 1.2 g/L more preferably from 0.9 to 1.1 g/L.

The concentration of the (d) alkali metal hydroxide leads to a pH value, which is strongly alkaline and has calculative a higher pH value than pH 14. The concentration of the (d) alkali metal hydroxide in aqueous alkaline cleaner solution is used from 65 to 200 g/L, preferably from 70 to 100 g/L, more preferably from 75 to 90 g/L.

It is noted that, throughout the specification and claims, the numerical limits of the disclosed ranges and ratios may be combined and are deemed to include all intervening values. Furthermore, all numerical values are deemed to be preceded by the modifier “about”, whether or not this term is specifically stated.

The at least one surfactant is selected from the group consisting of saturated branched or unbranched C5 to C12 carboxylic acid or salt thereof and is preferably a saturated branched C6 to C10 carboxylic acid or salt, preferable hexanoic acid, octanoic acid and decanoic acid or salt thereof, most preferably hexanoic acid and octanoic acid or salt thereof. The surfactant selected from the group consisting of saturated unbranched C6 to C10 carboxylic acid or salt, more preferably saturated unbranched C6 to C8 carboxylic acid or salt is preferably unsubstituted hexanoic acid and octanoic acid.

The at least one surfactant selected from the group consisting of saturated branched or unbranched C5 to C12 alkyl having a negatively charged group selected from sulfate, sulfite, sulfonate, phosphate, phosphite and carbonate is preferably selected from the group consisting of saturated branched or unbranched C5 to C8 alkyl, e.g. n-pentyl, iso-pentyl, n-hexyl, 2-ethylhexyl, n-heptyl, or n-octyl, having a negatively charged group of sulfate, phosphate and carbonate, more preferably having a negatively charged group of sulfate, most preferably the surfactant is sodium 2-ethylhexyl sulfate or sodium iso-heptyl sulfate.

The positive counter ion of the saturated branched or unbranched C5 to C12 alkyl having a negatively charged group is preferably sodium or potassium, more preferably sodium.

The saturated C3-C8 alkyl amino carboxylate is preferably a compound of formula (III) or (IV)

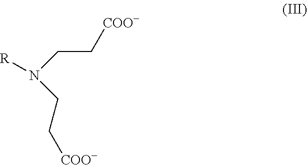

wherein R is branched or unbranched C4-C8 alkyl, e.g. n-pentyl, iso-pentyl, n-hexyl, 2-ethylhexyl, n-heptyl, n-octyl.
or

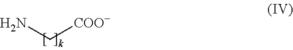

wherein k is an integer from 3 to 8, preferably from 4 to 6, most preferred 6.

It is understood that the surfactant is preferably added as salt. The positive counter ion of the saturated C3-C8 alkyl amino carboxylate is preferably sodium or potassium, more preferably sodium.

The at least one compound (c) is selected from the group consisting of alkoxylated C5-C12 alkanol and glycosidic C5-C12 alkanol.

The alkoxylated C5-C12 alkanol of compound (c) is preferably a compound of formula (I)

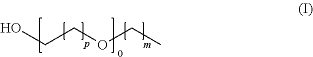

wherein p is an integer from 1 to 2, o is an integer from 4 to 10 and m is an integer from 4 to 9, more preferably p is 1, o is from 5 to 7 and m is from 5 to 7. Most preferably the alkoxylated C5-C12 alkanol is ethoxylated hexanol or ethoxylated octanol wherein o is 6.

The average MW (Molecular Weight) of the compound of formula (I) is from 200 to 15000 g/mol, preferably from 400 to 1000 g/mol, most preferably from 300 to 600 g/mol.

The glycosidic C5-C12 alkanol of compound (c) is preferably a compound of formula (II)

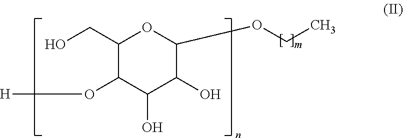

wherein n is an integer from 1 to 5 and m is an integer from 4 to 9, preferred from 5 to 7. Preferably the compound is an alkylpolyglucoside (APG) provided under CAS 54549-24-5.

Preferably the alkali metal hydroxide is sodium hydroxide or potassium hydroxide, more preferred sodium hydroxide.

In a preferred embodiment, the aqueous alkaline cleaner solution of the present invention comprises the (a) at least one surfactant selected from the group consisting of hexanoic acid and octanoic acid or salt thereof; the (b) at least one surfactant selected from the group consisting of sodium 2-ethylhexyl sulfate (sodium etasulfate), sodium iso-heptyl sulfate and alkyl amino carboxylate according to formula (III) wherein R is 2-ethylhexyl or n-octyl, and according to formula (IV) wherein k is from 4 to 6; the (c) at least one compound selected from the group consisting of a alkoxylated C5-C12 alkanol, being a compound of formula (I) wherein the compound is ethoxylated hexanol, ethoxylated octanol or ethoxylated decanol wherein o is 6, and a glycosidic C5-C12 alkanol, being a compound of formula (II) wherein n is an integer from 1 to 5 and m is an integer from 5-7; and (d) is sodium hydroxide. In a more preferred embodiment, the aqueous alkaline cleaner solution of the present invention further comprises (e) at least one water-soluble alkanolamine.

In a more preferred embodiment, the inventive aqueous alkaline cleaner solution comprises the following combinations of (b) sodium etasulfate and (c) ethoxylated hexan-1-ol; (b) 1-amino-hexyl carboxylate and (c) ethoxylated decan-1-ol; or (b) APG and (c) 2-ethylhexyl imino dipropionate. Preferably these combinations are used together with (a) hexanoic acid and (d) sodium hydroxide. In an even more preferred embodiment, the foregoing combinations are used together with monoethanolamine. Most preferred the inventive aqueous alkaline cleaner solution consists of the foregoing combinations.

Preferably the aqueous alkaline cleaner solution comprises additionally (e) at least one water-soluble alkanolamine selected from the group consisting of monoethanolamine (MEA), diethanolamine (DEA) and triethanolamine (TEA), preferably 2-aminoethanol. By using the water-soluble alkanolamine clouding of the solutions can be avoided. In own experiments it could be shown, that clouded solutions leads to undesired plating results.

The concentration of the at least one water-soluble alkanolamine is from 6.5 to 9.0 g/L, preferably from 7.5 to 8.5 g/L, more preferably from 7.8 to 8.2 g/L.

The method can be used in vertical and horizontal plating equipment. Preferably the method is used in vertical plating equipment, wherein the substrate is conveyed by a transport device to be processed through the treatment modules of the plating equipment.

The inventive method is preferably used, if the (iii) treating is conducted at 55 to 65° C. for 3 to 7 min. The low temperature reduces the energy consumption and also reduces equipment costs for using higher temperatures. Besides this, the evaporation of low boiling components can be prevented and has strong suction can be avoided.

In a preferred embodiment of the inventive method step (iv) is performed for 5 to 20 min at a temperature from 80° C. to 100° C., preferable for 10 to 15 min at a temperature from 85° C. to 95° C., in order to get a dry surface. The drying step can be performed by e.g. infrared heating, conventional heating, heated air blowing or combinations thereof.

It is important, that the surface is dry, preferably water-free to avoid undesired chemical or physical reactions and consequently to achieve best result for the subsequent treatment steps. The drying steps surprisingly allows to postpone the following treatment steps or to stop the whole process for a certain time before starting with subsequent process steps without harming, deteriorating or damaging the nonconductive surface while waiting. This is in particular useful if the desmear process shall be separately (locally and/or timely) performed because of different requirements to chemistry and/or necessary process time. The separate performance can be done in different treatment modules, one for cleaning and one for pretreating.

In one embodiment, the inventive method further comprises after step (iv) an additional step (vi) treating the surface of step (iv) with an aqueous alkaline cleaner solution comprising ethanolamine. This step could be performed within the cleaning module, within a stand-alone module or within the pretreating module according to the following process steps. If step (vi) is performed within the cleaning module or within a stand-alone module, it can be omitted within the pretreating steps (v) to (ix) below.

The inventive method therefore can be used as first part of a metallization process of the nonconductive surface comprising cleaning, pretreating and metallization. The inventive method is preferably used before activating the nonconductive surface, e.g. by using a palladium activator solution, for subsequent metallization for the manufacturing an article with an integrated circuit e.g. multilayer assemblies as fine line IC substrate articles.

Therefore, the method can as non-limiting example preferably further comprise the steps for pretreating the surface after step (iv) in order to prepare the surface for a subsequent electroless and/or electrolytic metallization, wherein the further steps comprising in this order:
optional step (v) treating the surface of step (iv) with an aqueous alkaline cleaner solution comprising ethanolamine;
step (vi) treating the surface of step (v) with an aqueous etch cleaner solution comprising persulfate;
step (vii) treating the surface of step (vi) with a pre-dip solution;
step (viii) treating the surface of step (vii) with an activator solution, preferably comprising precious metal ions, metal colloids or carbon-containing compound; and
step (ix) treating the surface of step (vii) with a reducer solution if the activator solution comprises precious metal ions.

Step (v) can be omitted if it is already done before.

In another embodiment of the invention, step (v) is optional. In a preferred embodiment, step (v) is performed to further improve the subsequent metallization results.

Step (v) is preferably performed at 50° to 70° C. for 3 to 7 min. In a preferred embodiment, the cleaner comprises 10 to 20 g/L sodium hydroxide and 10 to 16 g/L ethanolamine (MEA).

Step (vi) is preferably performed at 25° to 40° C. for 1 to 2 min. In a preferred embodiment, the cleaner comprises 100 to 150 g/L sodium persulfate and 30 to 45 g/L sulfuric acid.

Optional step (vii) treating the surface of step (vi) with a pre-dip solution. The pre-dip solution is an aqueous solution preferably comprising a pH regulator, preferably as sulfuric acid and/or sodium hydrogensulfate and a non-ionic surfactant. The non-ionic surfactant is preferably a polyethylene glycol (PEG) compound, more preferably PEG 1500 MW or PEG 10,000 MW.

The pre-dip solution is preferably an acidic aqueous pre-dip solution. The preferred pH is from 2 to 4.

Step (viii) treating the surface of step (vii) with an activator solution, preferably comprising precious metal ions, metal colloids or carbon-containing compound. The activator solution is preferably an aqueous solution comprising precious metal ions or metal colloids The activator solution is applied onto the surfaces of the nonconductive layer, preferably treating the surface with an aqueous palladium activator solution wherein a palladium ion layer is deposited onto the surfaces of the nonconductive layer of step (viii). Other useful activator solution known in the art may comprise carbon, conductive polymers or metal colloids containing e.g. copper or palladium-tin, for subsequent electrolytic direct metallization.

The palladium activator solution comprises at least one source of palladium ions. Additionally, the solution may comprise other sources of metal ions, as sources of ruthenium ions, sources of rhodium ions, sources of palladium ions, sources of osmium ions, sources of iridium ions, sources of platinum ions, sources of copper ions, sources of silver ions, sources of nickel ions, sources of cobalt ions, sources of gold ions and mixtures thereof. The palladium ions and said additional metal ions are being adsorbed on the surface of said substrate.

(ix) treating the substrate of step (viii), in case a palladium activator solution was used, with a palladium reduction solution wherein the deposited palladium ion layer in step (viii) is transformed into a metallic palladium layer.

Treating the surface of substrate comprising at least the palladium ions is conducted with a palladium reduction solution comprising at least one reducing agent suitable to reduce the metal ions to metallic state (at least the palladium ions) adsorbed on the surface of said substrate selected from the group consisting of boron based reducing agents, sources of hypophosphite ions, hydrazine and hydrazine derivatives, ascorbic acid, iso-ascorbic acid, sources of formaldehyde, glyoxylic acid, sources of glyoxylic acid, glycolic acid, formic acid, sugars, and salts of aforementioned acids.

The inventive method further comprises step (x) for electroless metallization and/or step (xi) for electrolytic metallization of the surface after step (viii) or (ix) in order to obtain a metallized surface, preferably a copper surface. Step (x) is preferred performed with an electroless copper plating bath to obtain a copper layer onto the layer of step (ix).

Generally, the electroless plating bath comprises a solvent, typically water, and at least one source of metal ions to be deposited. Further optional components are complexing agents (or chelating agents) for said metal ions (e.g. those mentioned below), reducing agents for said metal ions, stabilizing agents, co-solvents, wetting agents and functional additives such as brighteners, accelerators, suppressors, anti-tarnish agents. Such baths and components are known in the art. The electroless copper plating bath may further comprise sources of nickel ions, sources of cobalt ions and mixtures thereof.

Electrolytic metallization of step (xi) of the surface after step (viii) is performed (in case a layer of carbon or conductive polymers is deposited on the surface of step ((vi) or (vii)) with an electrolytic copper or nickel plating bath to obtain a copper layer or nickel layer onto the surface while filling the BMV with copper or nickel. The copper or nickel layer can be a copper alloy or a nickel alloy comprising alloying metals as tungsten, silver.

If needed, additional steps as rinsing steps e.g. with DI water or aqueous acidic or alkaline solutions; etch cleaner steps; pre-dip steps; and/or drying steps can be conducted between the steps above.

The used bath compositions and solutions as such except of the inventive solution in the steps above are well-known in the art. Suitable solutions for desmear process, palladium activator solution, palladium reduction solution, electroless and electrolytic copper solution are known to the public and can be purchased e.g. as Securiganth® MV Cleaner PF, Neoganth® MV Etch Cleaner, Neoganth® MV Activator, Neoganth® MV Reducer, Printoganth® MV and Cupracid® AC from Atotech Deutschland GmbH.

In a preferred embodiment of the invention the electrolytic plating bath in step (xi) is an electrolytic copper plating bath to obtain a copper layer. The resulting substrate of step (xi) can be used to build a multilayer assembly by using the following steps of an SAP application:

In one embodiment the copper layer of step (xi) can be structured by known process steps including applying a photoresist, structuring, patterning, stripping the photoresist and final etching down to the nonconductive layer surface to obtain a conductive structure onto the nonconductive layer.

The invention will now be illustrated by reference to the following FIGURES and non-limiting examples.

### EXAMPLES

The relative ratio of the used compounds of the present invention within the examples were found as preferable useful but are not considered as limiting. All components of the test solutions were diluted in DI (DI-De-Ionized water).

Three sets of test examples—Legs 1, 2, 3, 4, 5, 6, 9, 10 (Inventive examples—Legs 5 and 6, and comparative example—Legs 1, 2, 3, 4, 9 and 10) were prepared.

All test coupon (Legs) were treated according to desmear process (t1-t3), wherein (t3) was performed with (Legs 1, 3, 5 and 9) and without conditioner (Legs 2, 4, 6 and 10) according to the following scheme:

| | | | | | Dwell |
|---|---|---|---|---|---|
| | | | | | time |
| Process | Products | Amount | | Temp | (min) |
| Sweller (t1) | Securiganth MV | 500 | ml/L | 60° C. | 3′ |
| | Sweller | | | | |
| | NaOH | 3 | g/L | | |
| Etching (t2) | MnO4⁻[g/L] | 60 | g/L | 80° C. | 20′ |
| | MnO4⁻[g/L] | | | | |
| | NaOH | 40 | g/L | | |
| Reduction (t3) | Reduction | 100 | m/L | 50° C. | 5′ |
| | conditioner MV | | | | |
| | H2SO4(50 wt %) | 90 | ml/L | | |
| Reduction (t3) | Reduction | 100 | m/L | 50° C. | 5′ |
| | solution MV | | | | |
| | H2SO4(50 wt %) | 90 | ml/L | | |

Inventive examples (Inventive example 1 (Leg 5 and 6) were treated with the aqueous alkaline cleaner solution (step (iii) having a solution temperature of 60° C. and a dwelling time of 5 min and were dried for 15 min at 90° C. according to step (iv).

Comparative examples (Leg 1 and 2) were treated without step (iii) but were dried for 15 min at 90° C. according to step (iv).

Comparative examples (Leg 9 and 10) were treated including step (iii) but without drying according to step (iv).

Comparative examples (Leg 3 and 4) were treated with step (iii) but were dried for 15 min at 90° C. before step (iii).

### Inventive Example 1 Using Aqueous Alkaline Cleaner Solution of Step (iii) (Leg 5, 6)

Concentrations in the solution:

| | | |
|---|---|---|
| Hexanoic acid | 1.4 | g/L |
| Sodium etasulfate | 0.8 | g/L |
| ethoxylated hexan-1-ol (Cas 31726-34-8) | 1.1 | g/L |
| Sodium hydroxide (NaOH) | 84 | g/L |
| MEA - Monoethanolamine (>98%) | 6.5 | g/L |

### 1. Visual Inspection by Naked Eye

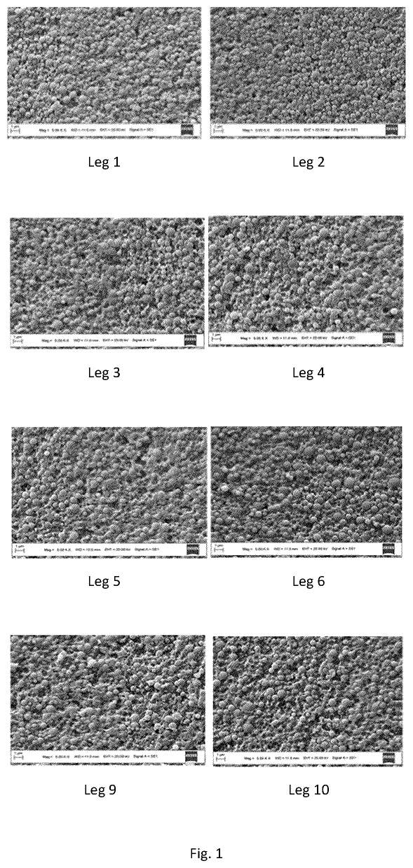

One set of test examples were used to take SEM picture, which are shown in FIG. 1 (via SEM imaging, magnification=5kx, showing the nonconductive surface of the nonconductive layer) to evaluate the glass filler removal performance (Leg 1, 2, 3, 4, 5, 6, 9, 10).

It can be seen that the cleaning results for Leg 1 and 2 were very poor, wherein many glass fillers remain on the surface. Leg 3 to 9 do all use step (iii) and therefore show comparable good cleaning results in contrast to Leg 1 and 2. However, best cleaning results were achieved for Leg 5 and 6 wherein slightly more glass fillers were removed in direct comparison to Leg 3, 4, 9 and 10.

### 2. Plating Results

Two set of test examples were used to further process Leg 1, 2, 3, 4, 5, 6, 9, 10 according to the following scheme according to steps (v)-(x):

| | | | | | Dwell time |
|---|---|---|---|---|---|
| Process | Products | Conc. | | Temp | (min) |
| Cleaner MEA | MEA | 10 | g/L | 60° C. | 5′ |
| (v) | NaOH | 15 | g/L | | |
| Etch Cleaner | 50% H₂SO₄ | 75 | ml/L | 30° C. | 1′ |
| (vi) | Sodium persulfate | 125 | g/L | | |
| Pre-dip | Pre dip MV Solution Neoganth | 10 | ml/L | RT | 1′ |
| (vii) | | | | | |
| Activator | Activator Neoganth MV | 200 | ppm | 45° C. | 5′ |
| (viii) | 45% NaOH | | | | |
| | pH | 11.3 | | | |
| Reducer | Reducer Neoganth MV | 7 | ml/L | 30° C. | 4′ |
| (ix) | | | | | |
| E'less copper | Printoganth MV basic solution | 140 | ml/L | 34° C. | 13′ |
| (x) | Printoganth MV TP1 copper | 85 | ml/L | | |
| | Printoganth MV TP1 Moderator | 3 | ml/L | | |
| | Printoganth MV stabilizer TP1 | 0.6 | ml/L | | |
| | Reduction solution Cu-14 | 32 | ml/L | | |
| | NaOH | 3.5 | g/L | | |

After step (ix) one set of test examples Leg 1, 2, 3, 4, 5, 6, 9, 10 were taken to determine the loading level of palladium onto the surface in [μg/dm²] palladium. The results can be seen in Tab. 1.

After step (x) one set of test examples Leg 1, 2, 3, 4, 5, 6, 9, 10 were taken to determine the loading level of palladium onto the surface in [μg/dm²] palladium. The results can be seen in Tab. 1.

TABLE 1

| | Loading Level Pd [ug/dm2] | Average Peel Strenght |
|---|---|---|
| | after step (ix) | after step (x) |
| Leg 1 | 58 | 0.301 |
| Leg 2 | 55 | 0.262 |
| Leg 3 | 51 | 0.356 |
| Leg 4 | 61 | 0.368 |
| Leg 5 | 43 | 0.378 |
| Leg 6 | 41 | 0.414 |
| Leg 9 | 57 | 0.35 |
| Leg 10 | 51 | 0.277 |

In Tab. 1 it can be seen that for Leg 5 and 6 the highest peel strength results could be achieved. Interestingly these results could be achieved while loading level of palladium onto the surface was at the lowest value. This saves palladium consumption, while on the other side reliability due to better peel strength could be improved.

1. Method for cleaning a nonconductive surface of a nonconductive layer, wherein the nonconductive layer is comprising a composite of an organic polymer and glass filler and comprising a blind micro via (BMV), for manufacturing an article with an integrated circuit, wherein the nonconductive surface comprises a nonconductive wall surface of the BMV, wherein the nonconductive layer is attached to a copper layer and wherein the copper layer forms the bottom of the BMV, wherein the method comprises the steps in the following order:
(i) providing the nonconductive surface of the nonconductive layer;
(ii) treating the provided surface with a desmear process comprising the following steps in this order: (t1) treatment with a sweller solution comprising water and an organic solvent, (t2) treatment with an aqueous etching solution comprising an oxidation agent, and (t3) treatment with an aqueous reduction solution comprising a reduction agent;
(iii) treating the surface treated in step (ii) with an aqueous alkaline cleaner solution in order to remove the glass filler, wherein the aqueous alkaline cleaner solution comprises:
(a) at least one surfactant selected from the group consisting of saturated branched or unbranched C5 to C12 carboxylic acid or salt thereof, wherein the concentration of the (a) at least one surfactant is from 0.9 to 1.7 g/L;
(b) at least one surfactant selected from the group consisting of saturated branched or unbranched C5 to C12 alkyl having a negatively charged group selected from sulfate, sulfite, sulfonate phosphate, phosphite and carbonate, and saturated C3-C8 alkyl amino carboxylate;
(c) at least one compound having at least one hydroxyl group and at least one C—O—C group wherein the compound is selected from the group consisting of alkoxylated C5-C12 alkanol and glycosidic C5-C12 alkanol; and
(d) alkali metal hydroxide, wherein the concentration of the (d) alkali metal hydroxide is from 65 to 200 g/L;
(iv) drying the surface treated in step (iii) in order to get a dry surface.

2. Method according to claim 1, wherein the step (iii) treating is conducted at 55 to 65° C. for 3 to 7 min.

3. Method according to claim 1, wherein step (iv) is performed for 5 to 20 min at a temperature from 80° C. to 100° C.

4. Method according to claim 1, wherein the method further comprises in order to prepare the surface for a subsequent electroless and/or electrolytic metallization after step (iv) an additional
step (v) treating the surface of step (iv) with an aqueous alkaline cleaner solution comprising ethanolamine.

5. Method according to claim 1, wherein the method further comprises steps for pretreating the surface after step (iv) in order to prepare the surface for a subsequent electroless and/or electrolytic metallization, wherein the further steps comprising in this order:
optional step (v) treating the surface of step (iv) with an aqueous alkaline cleaner solution comprising ethanolamine;
step (vi) treating the surface of step (v) with an aqueous etch cleaner solution comprising persulfate;
optional step (vii) treating the surface of step (vi) with a pre-dip solution;
step (viii) treating the surface of step (vii) with an activator solution; and
step (ix) treating the surface of step (vii) with a reducer solution if the activator solution comprises precious metal ions.

6. Method according to claim 5, wherein the method further comprises step (x) for electroless metallization and/or step (xi) for electrolytic metallization of the surface after step (viii) or (ix) in order to obtain a metallized surface.

7. Method according to claim 1, wherein the nonconductive layer attached to the copper layer are building a substrate, wherein the substrate has the nonconductive surface of the nonconductive layer and a copper surface of the copper layer.

8. Method according to claim 1, wherein the copper layer attached to the nonconductive layer is further attached to a core layer, preferably the core layer is a FR-1, FR-2, FR-3, FR-4, FR-5, copper-clad materials, SAP material or IC substrate and laminates thereof.

9. Method according to claim 1, wherein the concentration of the (b) at least one surfactant is used from 0.5 to 10 g/L and/or wherein the concentration of the (c) at least one compound is used from 0.6 to 1.3 g/L.

10. Method according to claim 1, wherein the (a) at least one surfactant is selected from the group consisting of saturated branched C6 to C10 carboxylic acid or salt.

11. Method according to claim 1, wherein the (b) at least one surfactant is selected from the group consisting of saturated branched or unbranched C5 to C8 alkyl having a negatively charged group of sulfate, phosphate and carbonate, and saturated C5-C8 alkyl amine carboxylate, preferably 1-amino (C5-C8) alkyl carboxylate.

12. Method according to claim 1, wherein the (c) at least one compound is an alkoxylated C5-C12 alkanol of formula (I) 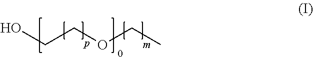
wherein p is an integer from 1 to 2, o is an integer from 4 to 10 and m is an integer from 4 to 9
and wherein the (c) at least one compound is a glycosidic C5-C12 alkanol of formula (II) 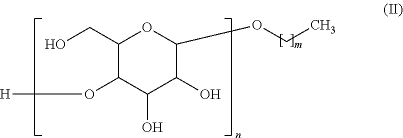
wherein n is an integer from 1 to 5 and m is an integer from 4 to 9.

13. Method according to claim 1, wherein the aqueous alkaline cleaner solution further comprises (e) at least one water-soluble alkanolamine, which is selected from the group consisting of monoethanolamine (MEA), diethanolamine (DEA) and triethanolamine (TEA), preferably 2-aminoethanol.

14. Method according to claim 13 wherein the concentration of the (e) at least one water-soluble alkanolamine is used from 6.5 to 9.0 g/L.

15. Method of applying a SAP (semi-additive process) in manufacturing an electronic article with an integrated circuit having line/space dimensions from 75/75 μm to 8/8 μm or less, comprising the method according to claim 1 to a nonconductive surface of a nonconductive layer.
